(19) United States
(12) Patent Application Publication
(10) Pub. No.: US 2022/0084847 A1
(43) Pub. Date: Mar. 17, 2022

(54) SUBSTRATE TREATING EQUIPMENT

(71) Applicant: SEMES CO., LTD., Chungcheongnam-do (KR)

(72) Inventors: JEE YOUNG LEE, Suwon-si (KR); YOUNG DAE CHUNG, Incheon (KR); JI HOON JEONG, Hwaseong-si (KR); TAE SHIN KIM, Suwon-si (KR); WON-GEUN KIM, Goyang-si (KR)

(21) Appl. No.: 17/346,410

(22) Filed: Jun. 14, 2021

(30) Foreign Application Priority Data
Sep. 14, 2020 (KR) 10-2020-00117842

(51) Int. Cl. H01L 21/67; F27B 17/00; F27D 3/00; F27D 5/00

(52) U.S. Cl. CPC H01L 21/67115; H01L 21/67023; F27D 5/0037; F27D 3/0084; F27B 17/0025

(57) ABSTRACT

Substrate treating equipment includes a first process chamber group including a plurality of process chambers, each of which includes a laser beam emitting unit that applies a laser beam to a substrate to heat the substrate, one laser beam generator that generates the laser beam applied to the substrate through the laser beam emitting unit of each of the plurality of process chambers included in the first process chamber group, and a beam shifting module including one or more mirrors corresponsable to the plurality of process chambers included in the first process chamber group. Each of the one or more mirrors is shifted to a position in which the mirror forms an optical path of the laser beam toward a predetermined one of the plurality of process chambers.

### CROSS-REFERENCE TO RELATED APPLICATIONS

A claim for priority under 35 U.S.C. § 119 is made to Korean Patent Application No. 10-2020-0117842 filed on Sep. 14, 2020, in the Korean Intellectual Property Office, the entire contents of which are hereby incorporated by reference.

### BACKGROUND

Embodiments of the inventive concept described herein relate to substrate treating equipment and a substrate treating method.

Various processes, such as photolithography, etching, ashing, ion implantation, thin-film deposition, cleaning, and the like, are performed on a substrate to manufacture semiconductor elements or a liquid crystal display. Among the various processes, the etching or cleaning process is a process of removing unnecessary areas from a thin film formed on the substrate. There is a need for high selectivity, high etch rate, and etch uniformity for the thin film, and with high integration of semiconductor elements, higher levels of etch selectivity and etch uniformity are required.

In general, in an etching or cleaning process, a chemical treatment step, a rinsing step, and a drying step are sequentially performed on a substrate. In the chemical treatment step, a chemical is dispensed onto the substrate to etch a thin film formed on the substrate or to remove foreign matter on the substrate, and in the rinsing step, a rinsing solution such as DI water is dispensed onto the substrate. The treatments of the substrate using the fluids may be accompanied by heating of the substrate.

### SUMMARY

Embodiments of the inventive concept provide substrate treating equipment for improving etching performance.

Embodiments of the inventive concept provide substrate treating equipment for accurately controlling the temperature of a substrate by rapidly raising and lowering the temperature of the substrate.

Embodiments of the inventive concept provide substrate treating equipment for effectively adjusting light distribution while heating a substrate by applying a laser beam to the substrate.

Embodiments of the inventive concept provide substrate treating equipment for effectively adjusting light intensity while heating a substrate by applying a laser beam to the substrate.

Embodiments of the inventive concept provide substrate treating equipment for reducing manufacturing cost.

Embodiments of the inventive concept provide substrate treating equipment for decreasing footprint (the amount of space occupied by the equipment).

Embodiments of the inventive concept provide substrate treating equipment and a substrate treating method for performing processes without delay in a plurality of substrate treating apparatuses using a single laser beam source.

Embodiments of the inventive concept provide substrate treating equipment for changing heating conditions depending on different environments for respective process chambers despite using a single laser beam generator.

The technical problems to be solved by the inventive concept are not limited to the aforementioned problems, and any other technical problems not mentioned herein will be clearly understood from the following description by those skilled in the art to which the inventive concept pertains.

According to an embodiment, substrate treating equipment includes a first process chamber group including a plurality of process chambers, each of which includes a laser beam emitting unit that applies a laser beam to a substrate to heat the substrate, one laser beam generator that generates the laser beam applied to the substrate through the laser beam emitting unit of each of the plurality of process chambers included in the first process chamber group, and a beam shifting module including one or more mirrors corresponsable to the plurality of process chambers included in the first process chamber group. Each of the one or more mirrors is shifted to a position in which the mirror forms an optical path of the laser beam toward a predetermined one of the plurality of process chambers.

In an embodiment, the beam shifting module may be optically connected to the laser beam emitting unit of each of the plurality of process chambers by a laser beam delivery member provided to correspond to the laser beam emitting unit.

In an embodiment, the laser beam delivery member may be implemented with an optical fiber.

In an embodiment, each of the plurality of mirrors may be shifted between the first position and the second position by rectilinear movement.

In an embodiment, each of the plurality of mirrors may be shifted between the first position and the second position by tilting.

In an embodiment, the tilting may be performed with a rotary shaft provided for the mirror as a center.

In an embodiment, the one laser beam generator may have a power output of several kW.

In an embodiment, each of the plurality of process chambers may further include a substrate support unit that supports and rotates the substrate and a liquid dispensing unit including a chemical dispensing nozzle that dispenses a chemical onto the substrate supported on the substrate support unit.

In an embodiment, the chemical dispensed by the liquid dispensing unit may be a liquid containing phosphoric acid.

In an embodiment, the substrate treating equipment may further include a controller. Each of the plurality of process chambers may perform a first process of dispensing the chemical onto the substrate and a second process of heating the substrate with the laser beam. The controller may perform control such that each of the plurality of process chambers included in the first process chamber group sequentially performs the first process and the second process over time and the plurality of process chambers simultaneously perform difference processes, and may control the beam shifting module such that the one or more mirrors form an optical path toward one process chamber in which the second process is performed, among the plurality of process chambers and deliver the laser beam generated from the one laser beam generator to the one process chamber in which the second process is performed.

In an embodiment, each of the plurality of process chambers may additionally perform a third process of dispensing a rinsing solution onto the substrate and replacing the chemical with the rinsing solution, and each of the plurality of process chambers included in the first process chamber group may sequentially perform the first process, the second process, and the third process over time.

In an embodiment, the substrate support unit may include a window member disposed under the substrate and formed of a material through which the laser beam emitted from the laser beam emitting unit is able to transmit, a chuck pin that supports a lateral portion of the substrate and spaces the substrate apart from the window member at a predetermined interval, a spin housing that is coupled with the window member and that has an empty space extending therethrough in an up/down direction and provides a path along which the laser beam is delivered, and a drive member that rotates the spin housing. The laser beam emitting unit may be disposed under the window member.

In an embodiment, the laser beam emitting unit may include a lens module that includes at least one lens unit and that refracts the laser beam to process the laser beam into a shape corresponding to the substrate, and a distance between the lens unit of the lens module and an end portion of the laser beam delivery member may be adjustable.

In an embodiment, each of the plurality of process chambers may further include a stage that moves the laser beam emitting unit upward and downward to adjust a distance between the laser beam emitting unit and the substrate.

According to an embodiment, provided is a method for treating a plurality of substrates using substrate treating equipment. The substrate treating equipment includes a plurality of process chambers, each of which treats a single substrate and one laser beam generator that generates a laser beam. Each of the plurality of process chambers performs a first process of dispensing a chemical onto the substrate and a second process of heating the substrate with the laser beam. Each of the plurality of process chambers sequentially performs the first process and the second process over time, and the plurality of process chambers simultaneously perform different processes. The laser beam generated from the one laser beam generator is optically connected with the plurality of process chambers through a plurality of optical paths. The laser beam is applied only to one process chamber along an optical path connected to the one process chamber in which the second process is performed, among the plurality of process chambers.

In an embodiment, optical paths connected to the remaining process chambers other than the one process chamber, in which the second process is performed, among the plurality of process chambers may be closed.

In an embodiment, each of the plurality of process chambers may additionally perform a third process of dispensing a rinsing solution onto the substrate and replacing the chemical with the rinsing solution, and each of the plurality of process chambers may sequentially perform the first process, the second process, and the third process over time.

In an embodiment, the one laser beam generator may have a power output of several kW.

In an embodiment, mirrors may be provided on the plurality of optical paths, respectively, and each mirror may form, in a first position, an optical path toward a corresponding one of the plurality of process chambers. The mirror may be able to be shifted to a second position in which the mirror does not obstruct an optical path of the laser beam. Among the mirrors, a mirror located on an upstream side of an optical path formed by a mirror located in the first position may be located in the second position, and the laser beam generated from the one laser beam generator may be delivered to a process chamber in which the second process is performed.

In an embodiment, the chemical dispensed in the first process may be a liquid containing phosphoric acid.

According to an embodiment, substrate treating equipment includes a first process chamber group including a plurality of process chambers, one laser beam generator that generates a laser beam, a beam shifting module including a plurality of mirrors corresponding to the plurality of process chambers included in the first process chamber group, and a controller. Each of the plurality of process chambers includes a substrate support unit that supports and rotates a substrate, a liquid dispensing unit including a chemical dispensing nozzle that dispenses a chemical onto the substrate supported on the substrate support unit, and a laser beam emitting unit that applies the laser beam to the substrate to heat the substrate. The substrate support unit includes a window member disposed under the substrate and formed of a material through which the laser beam emitted from the laser beam emitting unit is able to transmit, a chuck pin that supports a lateral portion of the substrate and spaces the substrate apart from the window member at a predetermined interval, a spin housing that is coupled with the window member and that has an empty space extending therethrough in an up/down direction and provides a path along which the laser beam is delivered, and a drive member that rotates the spin housing. The laser beam emitting unit is disposed under the window member, and the beam shifting module is optically connected by a laser beam delivery member connected with the laser beam emitting unit of each of the plurality of process chambers. Each of the plurality of mirrors is shifted between a first position in which the mirror forms an optical path of the laser beam toward a corresponding one of the plurality of process chambers and a second position in which the mirror does not obstruct the optical path of the laser beam. The controller performs control such that a mirror that forms an optical path toward a selected one of the plurality of process chambers is located in the first position, a mirror located on an upstream side of the optical path formed by the mirror located in the first position among the plurality of mirrors is located in the second position, and the laser beam generated from the one laser beam generator is delivered to the selected process chamber.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a plan view illustrating substrate treating equipment according to an embodiment of the inventive concept;

FIG. 2 is a sectional view illustrating a substrate treating apparatus provided in a process chamber of FIG. 1 according to an embodiment;

FIG. 3 is a side view of a laser beam emitting unit according to a first embodiment;

FIG. 4 is a schematic sectional view illustrating a first use state of the laser beam emitting unit according to the first embodiment of FIG. 3;

FIG. 5 is a schematic sectional view illustrating a second use state of the laser beam emitting unit according to the first embodiment of FIG. 3;

FIG. 6 illustrates a laser beam intensity change depending on adjustment of the distance between an end portion of a first laser beam delivery member and a lens unit;

FIG. 7 is a side view of a laser beam emitting unit according to a second embodiment;

FIG. 8 is a schematic sectional view illustrating a beam shifting module according to a first embodiment of the inventive concept;

FIG. 9 is a schematic view illustrating another embodiment of a connection relationship between a laser beam generator and the beam shifting module of the inventive concept;

FIGS. 10 to 12 sequentially illustrate operations of substrate treating equipment to which the beam shifting module according to the first embodiment of the inventive concept is applied;

FIGS. 13 to 15 sequentially illustrate operations of substrate treating equipment to which a beam shifting module according to a second embodiment of the inventive concept is applied;

FIGS. 16 to 18 sequentially illustrate operations of substrate treating equipment to which a beam shifting module according to a third embodiment of the inventive concept is applied; and

FIG. 19 is a flowchart illustrating a method for operating substrate treating equipment according to an embodiment of the inventive concept.

### DETAILED DESCRIPTION

Hereinafter, embodiments of the inventive concept will be described in detail with reference to the accompanying drawings such that those skilled in the art to which the inventive concept pertains can readily carry out the inventive concept. However, the inventive concept may be implemented in various different forms and is not limited to the embodiments described herein. Furthermore, in describing the embodiments of the inventive concept, detailed descriptions related to well-known functions or configurations will be omitted when they may make subject matters of the inventive concept unnecessarily obscure. In addition, components performing similar functions and operations are provided with identical reference numerals throughout the accompanying drawings.

The terms “include” and “comprise” in the specification are “open type” expressions just to say that the corresponding components exist and, unless specifically described to the contrary, do not exclude but may include additional components. Specifically, it should be understood that the terms “include”, “comprise”, and “have”, when used herein, specify the presence of stated features, integers, steps, operations, components, and/or parts, but do not preclude the presence or addition of one or more other features, integers, steps, operations, components, parts, and/or groups thereof.

The terms of a singular form may include plural forms unless otherwise specified. Furthermore, in the drawings, the shapes and dimensions of components may be exaggerated for clarity of illustration.

In this embodiment, a process of etching a substrate using a treatment liquid will be described as an example. However, without being limited thereto, this embodiment is applicable to various substrate treating processes using liquids, such as a cleaning process, an ashing process, a developing process, and the like.

Here, the substrate may have a comprehensive concept that includes all substrates used to manufacture semiconductor elements, flat panel displays (FPDs), and other objects having circuit patterns formed on thin films. Examples of the substrate include a silicon wafer, a glass substrate, an organic substrate, and the like.

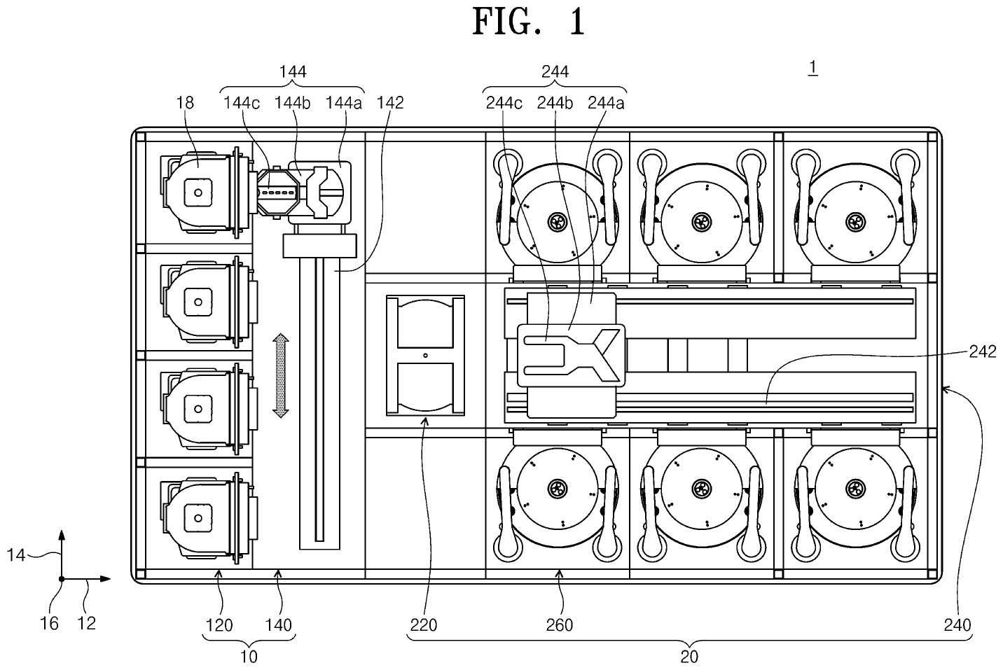

Hereinafter, embodiments of the inventive concept will be described in detail with reference to FIGS. 1 to 19.

FIG. 1 is a plan view illustrating substrate treating equipment 1 according to an embodiment of the inventive concept. Referring to FIG. 1, the substrate treating equipment 1 includes an index module 10 and a process module 20. The index module 10 includes a load port 120 and a transfer frame 140. The load port 120, the transfer frame 140, and the process module 20 are sequentially arranged in a row.

Hereinafter, a direction in which the load port 120, the transfer frame 140, and the process module 20 are arranged is referred to as a first direction 12, a direction perpendicular to the first direction 12 when viewed from above is referred to as a second direction 14, and a direction perpendicular to a plane including the first direction 12 and the second direction 14 is referred to as a third direction 16.

A carrier 18 having substrates W received therein is seated on the load port 120. A plurality of load ports 120 may be provided. The load ports 120 may be disposed in a row along the second direction 14. The number of load ports 120 may be increased or decreased depending on process efficiency and footprint of the process module 20. The carrier 18 has a plurality of slots (not illustrated) formed therein in which the substrates W are received in a state of being horizontally disposed with respect to the ground. A front opening unified pod (FOUP) may be used as the carrier 18.

The process module 20 includes a buffer unit 220, a transfer chamber 240, and a process chamber 260.

The transfer chamber 240 is disposed such that the lengthwise direction thereof is parallel to the first direction 12. A plurality of process chambers 260 may be disposed on one side or opposite sides of the transfer chamber 240. On the opposite sides of the transfer chamber 240, the plurality of process chambers 260 may be disposed to be symmetric with respect to the transfer chamber 240. Some of the process chambers 260 are disposed along the lengthwise direction of the transfer chamber 240. Furthermore, other process chambers 260 are stacked one above another. That is, the process chambers 260 may be disposed in an A×B array on the one side of the transfer chamber 240. Here, “A” denotes the number of process chambers 260 provided in a row along the first direction 12, and “B” denotes the number of process chambers 260 provided in a column along the third direction 16. When four or six process chambers 260 are provided on the one side of the transfer chamber 240, the process chambers 260 may be disposed in a 2×2 or 3×2 array. The number of process chambers 260 may be increased or decreased. Alternatively, the process chambers 260 may be provided on only the one side of the transfer chamber 240. In another case, the process chambers 260 may be disposed in a single layer on the opposite sides of the transfer chamber 240.

The buffer unit 220 is disposed between the transfer frame 140 and the transfer chamber 240. The buffer unit 220 provides a space in which the substrates W stay before transferred between the transfer chamber 240 and the transfer frame 140. The buffer unit 220 has slots (not illustrated) formed therein in which the substrates W are received. The slots (not illustrated) are spaced apart from each other along the third direction 16. The buffer unit 220 is open at one side facing the transfer frame 140 and at an opposite side facing the transfer chamber 240.

The transfer frame 140 transfers the substrates W between the carriers 18 seated on the load ports 120 and the buffer unit 220. An index rail 142 and an index robot 144 are provided in the transfer frame 140. The index rail 142 is disposed such that the lengthwise direction thereof is parallel to the second direction 14. The index robot 144 is installed on the index rail 142 and rectilinearly moves along the index rail 142 in the second direction 14. The index robot 144 includes a base 144a, a body 144b, and an index arm 144c. The base 144a is movable along the index rail 142. The body 144b is coupled to the base 144a. The body 144b is movable on the base 144a along the third direction 16. Furthermore, the body 144b is rotatable on the base 144a. The index arm 144c is coupled to the body 144b and is movable forward and backward relative to the body 144b. A plurality of index arms 144c may be provided. The index arms 144c may be individually driven. The index arms 144c may be stacked one above another with a spacing gap therebetween along the third direction 16. Some of the index arms 144c may be used to transfer the substrates W from the process module 20 to the carriers 18, and the other index arms 144c may be used to transfer the substrates W from the carriers 18 to the process module 20. Accordingly, particles generated from the substrates W that are to be treated may be prevented from adhering to the treated substrates W in the process in which the index robot 144 transfers the substrates W between the carriers 18 and the process module 20.

The transfer chamber 240 transfers the substrates W between the buffer unit 220 and the process chambers 260 and between the process chambers 260. A guide rail 242 and a main robot 244 are provided in the transfer chamber 240. The guide rail 242 is disposed such that the lengthwise direction thereof is parallel to the first direction 12. The main robot 244 is installed on the guide rail 242 and rectilinearly moves on the guide rail 242 along the first direction 12. The main robot 244 includes a base 244a, a body 244b, and a main arm 244c. The base 244a is movable along the guide rail 242. The body 244b is coupled to the base 244a. The body 244b is movable on the base 244a along the third direction 16. Furthermore, the body 244b is rotatable on the base 244a. The main arm 244c is coupled to the body 244b and is movable forward and backward relative to the body 244b. A plurality of main arms 244c may be provided. The main arms 244c may be individually driven. The main arms 244c may be stacked one above another with a spacing gap therebetween along the third direction 16.

The process chambers 260 are equipped with substrate treating apparatuses 300 for performing liquid treatment processes on the substrates W. The substrate treating apparatuses 300 may have different structures depending on the types of liquid treatment processes performed by the substrate treating apparatuses 300. Alternatively, the substrate treating apparatuses 300 in the respective process chambers 260 may have the same structure. Selectively, the process chambers 260 may be divided into a plurality of groups. The substrate treating apparatuses 300 in the process chambers 260 belonging to the same group may have the same structure, and the substrate treating apparatuses 300 in the process chambers 260 belonging to different groups may have different structures.

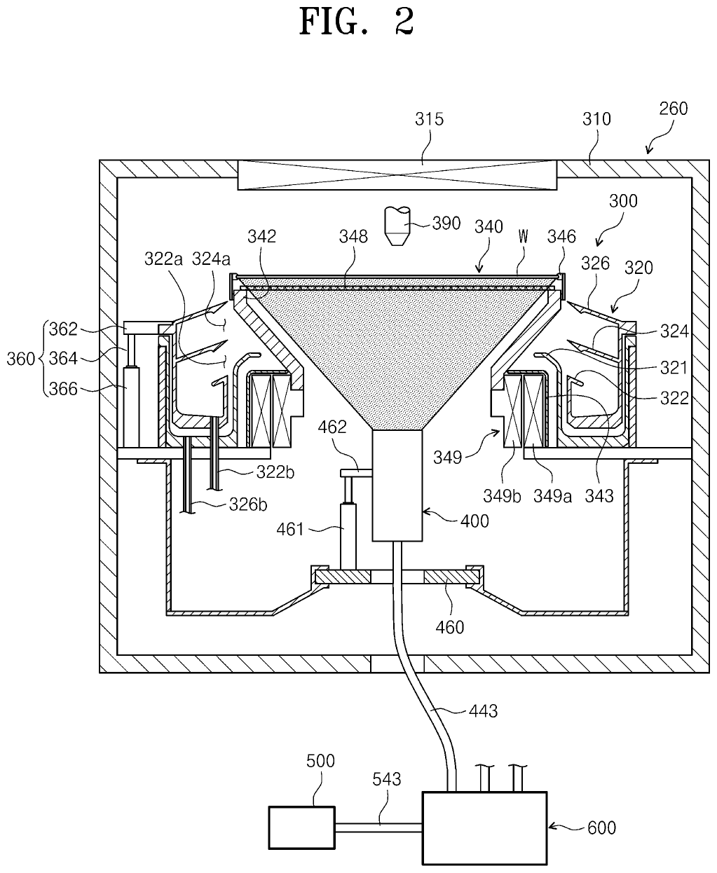

FIG. 2 is a sectional view illustrating the substrate treating apparatus 300 provided in the process chamber 260 of FIG. 1 according to an embodiment. Referring to FIG. 2, the substrate treating apparatus 300 includes a treatment vessel 320, a substrate support unit 340, a lifting unit 360, a liquid dispensing unit 390, and a controller (not illustrated).

The treatment vessel 320 has a container shape that is open at the top. The treatment vessel 320 includes a first recovery bowl 321 and a second recovery bowl 322. The recovery bowls 321 and 322 recover different treatment liquids used for processes. The first recovery bowl 321 has an annular ring shape that surrounds the substrate support unit 340. The second recovery bowl 322 has an annular ring shape that surrounds the substrate support unit 340. In an embodiment, the first recovery bowl 321 has an annular ring shape that surrounds the second recovery bowl 322. The second recovery bowl 322 may be inserted into the first recovery bowl 321. The height of the second recovery bowl 322 may be greater than the height of the first recovery bowl 321. The second recovery bowl 322 may include a first guide part 326 and a second guide part 324. The first guide part 326 may be provided at the top of the second recovery bowl 322. The first guide part 326 may extend toward the substrate support unit 340. The first guide part 326 may be formed to be upwardly inclined toward the substrate support unit 340. In the second recovery bowl 322, the second guide part 324 may be spaced apart downward from the first guide part 326. The second guide part 324 may extend toward the substrate support unit 340. The second guide part 324 may be formed to be upwardly inclined toward the substrate support unit 340. A first inlet 324a through which a treatment liquid is introduced is formed between the first guide part 326 and the second guide part 324. A second inlet 322a is provided under the second guide part 324. The first inlet 324a and the second inlet 322a may be located at different heights. The second guide part 324 may have a hole (not illustrated) formed therein, and the treatment liquid introduced through the first inlet 324a may flow, through the hole (not illustrated), to a second recovery line 322b connected to the bottom of the second recovery bowl 322. The hole (not illustrated) of the second guide part 324 may be formed in the lowest position of the second guide part 324. A treatment liquid recovered by the first recovery bowl 321 flows to a first recovery line 321b connected to the bottom of the first recovery bowl 321. The treatment liquids introduced into the recovery bowls 321 and 322 may be supplied to an external treatment liquid regeneration system (not illustrated) through the recovery lines 321b and 322b and may be regenerated by the regeneration system.

The lifting unit 360 rectilinearly moves the treatment vessel 320 in an up/down direction. For example, the lifting unit 360 may be coupled to the second recovery bowl 322 of the treatment vessel 320 and may move the second recovery bowl 322 in the up/down direction to change the height of the treatment vessel 320 relative to the substrate support unit 340. The lifting unit 360 includes a bracket 362, a movable shaft 364, and an actuator 366. The bracket 362 is fixedly attached to an outer wall of the treatment vessel 320, and the movable shaft 364 is fixedly coupled to the bracket 362 and is moved in the up/down direction by the actuator 366. The second recovery bowl 322 of the treatment vessel 320 is moved downward such that, when a substrate W is loaded onto or unloaded from the substrate support unit 340, an upper portion of the substrate support unit 340 protrudes above the treatment vessel 320. Specifically, the second recovery bowl 322 of the treatment vessel 320 is moved downward such that the upper portion of the substrate support unit 340 further protrudes beyond the first guide part 326. Furthermore, when a process is performed, the height of the treatment vessel 320 is adjusted depending on the types of treatment liquids dispensed onto the substrate W, such that the treatment liquids are introduced into the preset recovery bowls 321 and 322. Alternatively, the lifting unit 360 may move the substrate support unit 340 instead of the treatment vessel 320 in the up/down direction. In another case, the lifting unit 360 may raise or lower the entire treatment vessel 320 in the up/down direction. The lifting unit 360 is provided to adjust the relative height between the treatment vessel 320 and the substrate support unit 340. Embodiments of the treatment vessel 320 and the lifting unit 360 may be provided in various structures and methods depending on designs as long as the relative height between the treatment vessel 320 and the substrate support unit 340 is able to be adjusted.

The substrate support unit 340 supports and rotates the substrate W during a process.

The substrate support unit 340 includes a window member 348, a spin housing 342, chuck pins 346, and a drive member 349.

The window member 348 is located under the substrate W. The window member 348 may have a shape substantially corresponding to the substrate W. For example, when the substrate W is a circular wafer, the window member 348 may have a substantially circular shape. The window member 348 may have the same diameter as the substrate W, or may have a smaller or larger diameter than the substrate W. The window member 348 may allow a laser beam to transmit through the window member 348 and reach the substrate W. The window member 348 may protect components of the substrate support unit 340 from a chemical and may be provided in various sizes and shapes depending on designs. The window member 348 may have a larger diameter than the substrate W.

The window member 348 may be formed of a material having high light transmittance. Accordingly, a laser beam emitted from a laser beam emitting unit 400 may transmit through the window member 348. The window member 348 may be formed of a material having excellent corrosion resistance so as not to react with a chemical. For example, the window member 348 may be formed of quartz, glass, sapphire, or the like.

The spin housing 342 may be provided on a bottom surface of the window member 348. The spin housing 342 supports an edge of the window member 348. The spin housing 342 has an empty space extending therethrough in the up/down direction. The empty space formed by the spin housing 342 may have a gradually increasing inner diameter toward the window member 348 from a portion adjacent to the laser beam emitting unit 400. The spin housing 342 may have a cylindrical shape, the inner diameter of which is gradually increased from a lower end to an upper end. The empty space in the spin housing 342 may allow a laser beam emitted from the laser beam emitting unit 400, which will be described below, to be applied to the substrate W without interference with the spin housing 342. A connecting portion between the spin housing 342 and the window member 348 may have an air-tight structure such that a chemical dispensed onto the substrate W does not flow toward the laser beam emitting unit 400.

The drive member 349 may be coupled with the spin housing 342 and may rotate the spin housing 342. Any member capable of rotating the spin housing 342 may be used as the drive member 349. For example, the drive member 349 may be a hollow motor. According to an embodiment, the drive member 349 includes a stator 349a and a rotor 349b. The stator 349a is fixed in one position, and the rotor 349b is coupled with the spin housing 342. In the illustrated embodiment, a hollow motor having the rotor 349b disposed inside and the stator 349a disposed outside is illustrated. A lower portion of the spin housing 342 may be coupled with the rotor 349b and may be rotated by rotation of the rotor 349b. In a case where a hollow motor is used as the drive member 349, a hollow motor having a small hollow space may be selected to correspond to the narrow lower portion of the spin housing 342. Accordingly, manufacturing cost may be reduced. According to an embodiment, the stator 349a of the drive member 349 may be fixedly coupled to a support wall on which the treatment vessel 320 is supported. According to an embodiment, the substrate support unit 340 may further include a cover member 343 that protects the drive member 349 from a chemical.

The liquid dispensing unit 390 may be a component for dispensing a chemical onto the substrate W from above the substrate W and may include at least one chemical dispensing nozzle. The liquid dispensing unit 390 may pump the chemical out of a storage tank (not illustrated), may deliver the chemical, and may dispense the chemical onto the substrate W through the chemical dispensing nozzle. The liquid dispensing unit 390 may include an actuator and may be movable between a process position directly above the center of the substrate W and a standby position outside the substrate W by the actuator.

The liquid dispensing unit 390 may dispense various chemicals onto the substrate W depending on substrate treating processes. In a process of etching a silicon nitride film, the liquid dispensing unit 390 may dispense a chemical containing phosphoric acid (H₃PO₄) onto the substrate W. The liquid dispensing unit 390 may further include a deionized water (DIW) dispensing nozzle for rinsing a substrate surface after an etching process, and an isopropyl alcohol (IPA) dispensing nozzle and a nitrogen (N₂) dispensing nozzle for performing a drying process after the rinsing process. Although not illustrated, the liquid dispensing unit 390 may include a nozzle moving member (not illustrated) that supports and moves the chemical dispensing nozzle. The nozzle moving member (not illustrated) may include a support shaft (not illustrated), an arm (not illustrated), and an actuator (not illustrated). The support shaft (not illustrated) is located on one side of the treatment vessel 320. The support shaft (not illustrated) has a rod shape, the lengthwise direction of which is parallel to the third direction 16. The support shaft (not illustrated) is rotatable by the actuator (not illustrated). The arm (not illustrated) is coupled to an upper end of the support shaft (not illustrated). The arm (not illustrated) may extend from the support shaft (not illustrated) at a right angle thereto. The chemical dispensing nozzle is fixedly coupled to an end of the arm (not illustrated). As the support shaft (not illustrated) is rotated, the chemical dispensing nozzle is able to swing together with the arm (not illustrated). The chemical dispensing nozzle may be moved between the process position and the standby position. Selectively, the support shaft (not illustrated) may be movable upward and downward. Furthermore, the arm (not illustrated) is movable forward and backward along the lengthwise direction thereof.

The laser beam emitting unit 400 is a component for applying a laser beam to the substrate W. The laser beam emitting unit 400 may be located under the window member 348 in the substrate support unit 340. The laser beam emitting unit 400 may emit a laser beam toward the substrate W located on the substrate support unit 340. The laser beam emitted from the laser beam emitting unit 400 may be applied to the substrate W through the window member 348 of the substrate support unit 340. Accordingly, the substrate W may be heated to a set temperature.

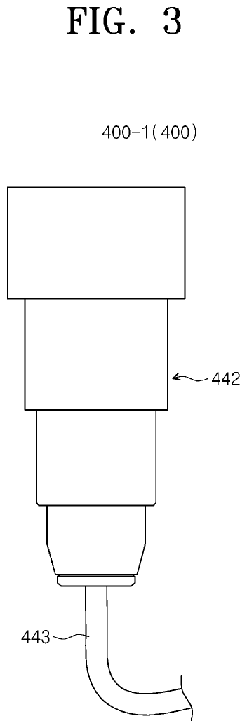

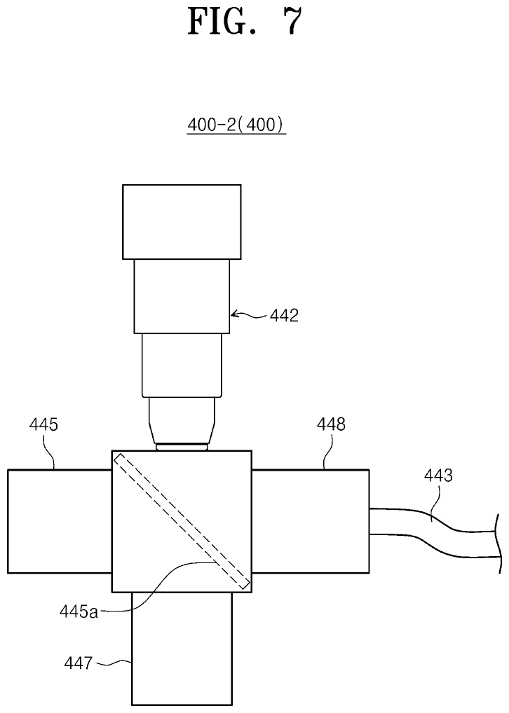

The laser beam emitting unit 400 may be configured to uniformly apply a laser beam to the entire surface of the substrate W. No special limitation applies to the laser beam emitting unit 400, as long as the laser beam emitting unit 400 is capable of uniformly applying a laser beam to the entire surface of the substrate W. Hereinafter, a laser beam emitting unit 400-1 according to a first embodiment will be described with reference to FIGS. 3 to 5, and a laser beam emitting unit 400-2 according to a second embodiment will be described with reference to FIG. 7.

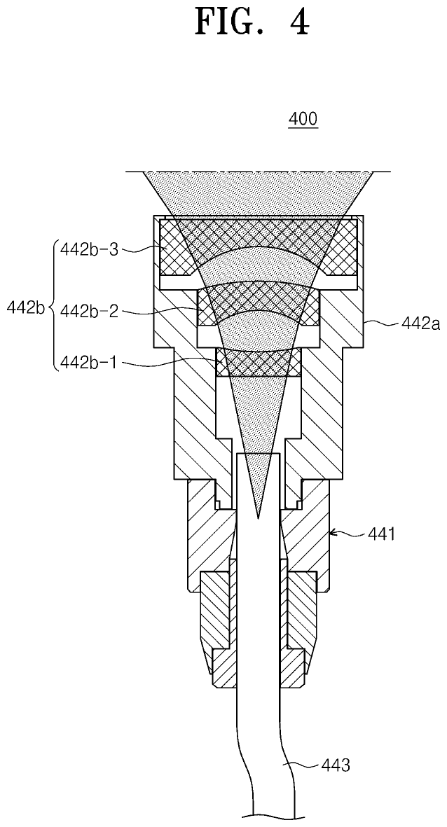

The laser beam emitting unit 400-1 according to the first embodiment will be described below with reference to FIGS. 3 to 5. FIG. 3 is a side view of the laser beam emitting unit 400-1 according to the first embodiment. Referring to FIG. 3, the laser beam emitting unit 400-1 may include a lens module 442. The laser beam emitting unit 400-1 may receive a laser beam from a first laser beam delivery member 443. FIG. 4 is a schematic sectional view illustrating a first use state of the laser beam emitting unit 400-1 according to the first embodiment of FIG. 3. Additionally, referring to FIG. 4, the lens module 442 includes a lens unit 442b and a lens barrel 442a that supports and accommodates the lens unit 442b. The lens unit 442b may be implemented by a combination of a plurality of lenses. For example, the lens unit 442b may include a concave lens or a convex lens. For example, the lens unit 442b may include a first lens 442b-1, a second lens 442b-2, and a third lens 442b-3. The first lens 442b-1 may have a concave upper surface and may cause a laser beam to diverge. The second lens 442b-2 may have a convex upper surface and a concave lower surface and may cause the laser beam to diverge. The third lens 442b-3 may have a concave lower surface and may cause the laser beam to diverge. Although the lens unit 442b is implemented by a combination of the three lenses 442b-1, 442b-2, and 442b-3, this is for convenience of description, and the number of lenses constituting the lens unit 442b and the types thereof may be variously selected depending on design of the substrate treating apparatus 300.

The first laser beam delivery member 443 is a component that delivers a laser beam generated from a laser beam generator 500 to the lens module 442. The first laser beam delivery member 443 may be, for example, an optical fiber. An end portion of the first laser beam delivery member 443 may be coupled to a fastening member 441, and the first laser beam delivery member 443 may be coupled with the lens module 442 through the fastening member 441. The fastening member 441 is configured to adjust the distance between the end portion of the first laser beam delivery member 443 and the lens unit 442b.

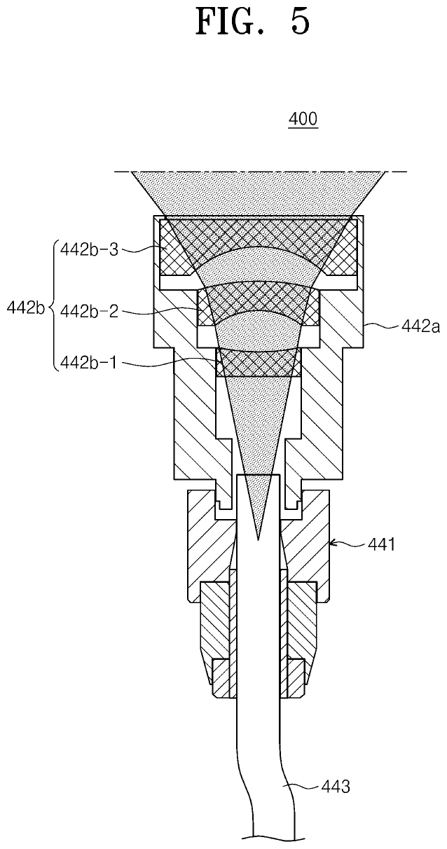

FIG. 5 is a schematic sectional view illustrating a second use state of the laser beam emitting unit 400-1 according to the first embodiment of FIG. 3. Referring to FIG. 5, in the second use state, the distance between the end portion of the first laser beam delivery member 443 and the lens unit 442b is greater than that in the first use state of FIG. 4. In the second use state of FIG. 5, a laser beam may be more widely distributed than in the first use state of FIG. 4, and the intensity of the laser beam may be adjusted.

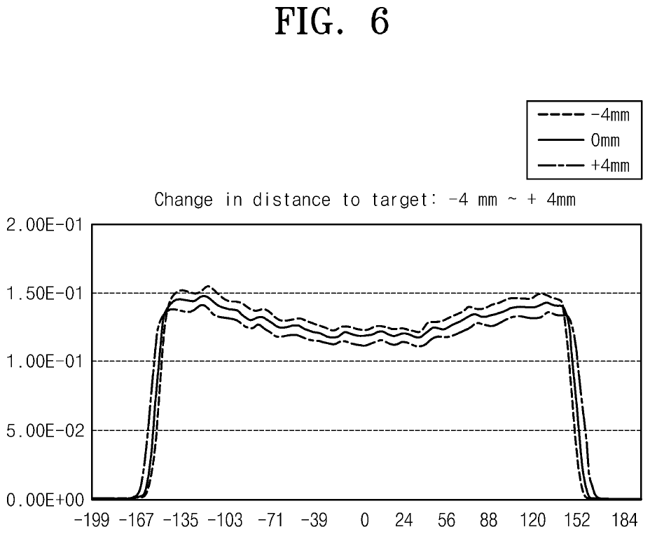

FIG. 6 illustrates a laser beam intensity change depending on adjustment of the distance between the end portion of the first laser beam delivery member 443 and the lens unit 442b. The Y-axis (vertical axis) represents the magnitude of intensity, and the X-axis (horizontal axis) represents the position of a laser beam relative to a 300-mm wafer. As the end portion of the first laser beam delivery member 443 moves toward the lens unit 442b, the magnitude of intensity is increased, and the irradiation area is narrowed. Through an experimental example, it can be seen that when the distance to a target (e.g., a wafer) is decreased by 4 mm, the magnitude of intensity is increased and the irradiation area is narrowed, as compared with when the distance to the target (e.g., a wafer) is increased by 4 mm.

Although not illustrated, the relative distances between the lenses constituting the lens unit 442b may be changed to adjust the irradiation area and the intensity for each area.

FIG. 7 is a side view of the laser beam emitting unit 400-2 according to the second embodiment. Referring to FIG. 7, the laser beam emitting unit 400-2 may include a reflecting unit 445, an imaging unit 446, a sensing unit 447, and a collimator 448. The reflecting unit 445 may reflect, toward a lens module 442, part of a laser beam generated from the laser beam generator 500 and delivered through a first laser beam delivery member 443 and may allow the rest to pass through. To this end, the reflecting unit 445 may include a reflecting mirror 145a installed at an angle of 45 degrees.

The imaging unit 446 may be coupled to the reflecting unit 445. The imaging unit 446 may photograph the laser beam passing through the reflecting unit 445 and may convert the laser beam into image data. The imaging unit 446 may analyze the image data to examine whether the laser beam is output from the laser beam generator 500 as designed and whether the laser beam is delivered through the first laser beam delivery member 443 as designed.

The sensing unit 447 may be coupled to the reflecting unit 445 and may sense the intensity of the laser beam input to the reflecting unit 445. The sensing unit 447 may be, for example, a photo detector. When the intensity of the laser beam is excessively high, the substrate W may be rapidly heated. In contrast, when the intensity of the laser beam is excessively low, it may take long time to heat the substrate W. The sensing unit 447 may determine whether the intensity of the laser beam is an appropriate value.

Although it has been described that the laser beam emitting unit 400 is disposed under the substrate W and applies a laser beam to the back side of the substrate W, the inventive concept is not limited thereto. The laser beam emitting unit 400 may be disposed over the substrate W and may apply a laser beam to the front side of the substrate W.

Referring again to FIG. 2, the laser beam emitting unit 400 may be coupled to an XYZ stage 460. The XYZ stage 460 may include a lifting actuator 461 and a coupling part 462 connected with the lifting actuator 461 and coupled with the laser beam emitting unit 400. The position of the laser beam emitting unit 400 relative to the substrate W may be adjusted by the XYZ stage 460. Furthermore, laser beam intensity may be adjusted by adjusting the distance between the laser beam emitting unit 400 and the substrate W through the lifting actuator 461.

The first laser beam delivery member 443 of the laser beam emitting unit 400 is one of a plurality of first laser beam delivery members 443 connected with a beam shifting module 600. The beam shifting module 600 may be optically connected with the laser beam generator 500. The optical connection between the laser beam generator 500 and the beam shifting module 600 may be made by a second laser beam delivery member 543. The second laser beam delivery member 543 may be implemented with an optical fiber. Alternatively, the second laser beam delivery member 543 may be implemented with a plurality of mirrors that form a light transmission path. In the case where the laser beam generator 500 and the beam shifting module 600 are optically connected by the second laser beam delivery member 543, the laser beam generator 500 and the beam shifting module 600 may be located in different positions, and thus the degree of freedom in design may be raised.

The laser beam generator 500 may generate a laser beam. The laser beam generator 500 may generate a laser beam with a wavelength that the substrate W is able to easily absorb. According to an embodiment, the laser beam generator 500 may be implemented with a high-power device having a power output of 4 kW to 5 kW. High-power beam energy has to be applied to the substrate W to heat the substrate W. A high-power laser beam generator is generally expensive, and therefore manufacturing cost is increased when one high-power laser beam generator is provided for each process chamber.

Meanwhile, according to an embodiment, the laser beam generator 500 may receive a signal of a pulse generator and may generate a laser beam in a pulse form. The pulse form may be a form in which a laser beam is turned on/off or a form in which the intensity of a laser beam is periodically changed from a first intensity to a second intensity and vice versa.

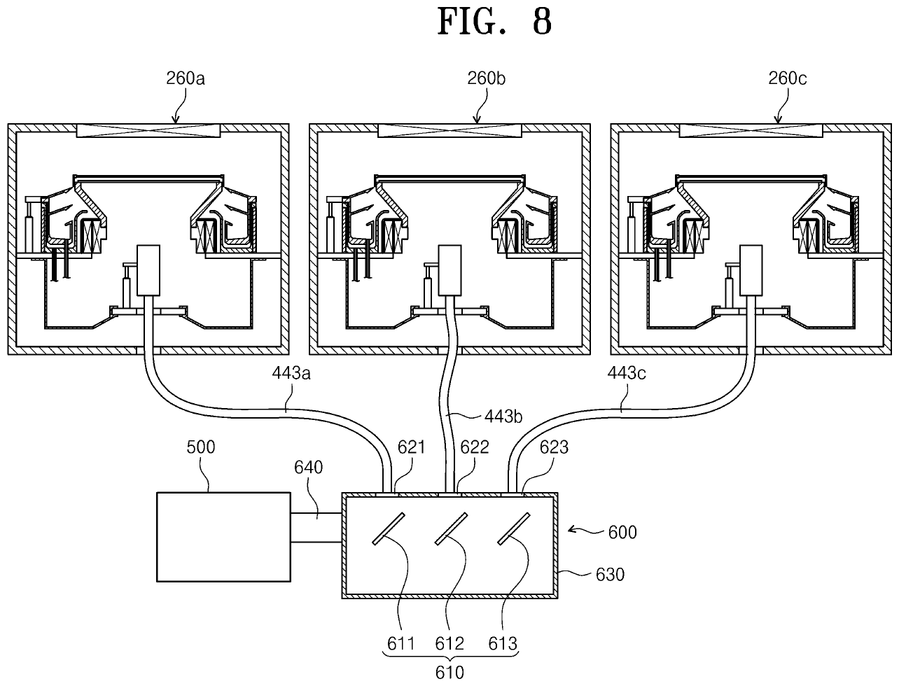

FIG. 8 is a schematic sectional view illustrating a beam shifting module 600 according to a first embodiment of the inventive concept. The beam shifting module 600 will be described below with reference to FIG. 8. The beam shifting module 600 includes a mirror unit 610. The mirror unit 610 includes as many mirrors as process chambers 260. For example, three process chambers 260a, 260b, and 260c are illustrated as an example of the process chambers 260. Three mirrors 611, 612, and 613 corresponding to the three process chambers 260a, 260b, and 260c, respectively, are illustrated. The mirror unit 610 may be provided inside a housing 630. The inside of the housing 630 may be provided in an environment in which interference of light is minimized. The first mirror 611 forms an optical path provided for the first process chamber 260a. The first mirror 611 delivers a laser beam to a first laser beam delivery member 443a directed toward the first process chamber 260a. The second mirror 612 forms an optical path provided for the second process chamber 260b. The second mirror 612 delivers a laser beam to a first laser beam delivery member 443b directed toward the second process chamber 260b. The third mirror 613 forms an optical path provided for the third process chamber 260c. The third mirror 613 delivers a laser beam to a first laser beam delivery member 443c directed toward the third process chamber 260c. Each of the mirrors provided in the mirror unit 610 is independently movable between a first position and a second position. The first position is a position in which the mirror forms a path along which a laser beam is reflected and delivered to a corresponding process chamber, and the second position is a position to which the mirror moves backward from the first position and in which the mirror does not change a path of a laser beam. The movement of the mirror may be performed by driving a motor connected to the mirror.

In an embodiment, when the second laser beam delivery member 543 connected with the laser beam generator 500 is implemented with an optical fiber, a collimator 640 may be provided on an end portion of the second laser beam delivery member 543. Meanwhile, the collimator 640 may be omitted when a laser beam generated from the laser beam generator 500 is collimated according to an embodiment.

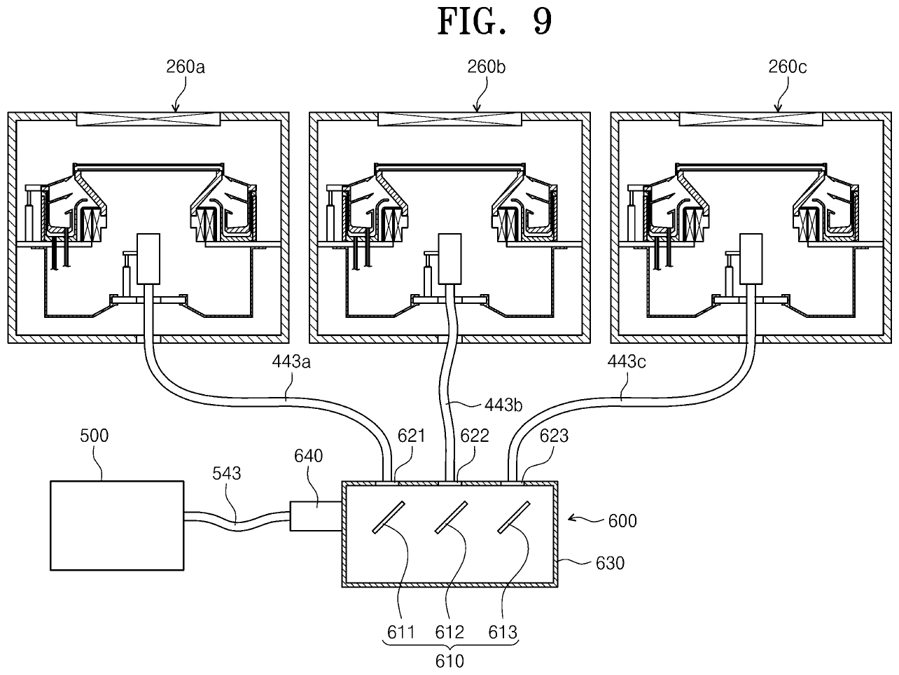

FIG. 9 is a schematic view illustrating another embodiment of a connection relationship between the laser beam generator 500 and the beam shifting module 600 of the inventive concept. According to the other embodiment, the second laser beam delivery member 543 may not be provided between the laser beam generator 500 and the beam shifting module 600, and the laser beam generator 500 and the beam shifting module 600 may be directly connected with each other. In the case where the laser beam generator 500 and the beam shifting module 600 are directly connected with each other, the collimator 640 may be omitted. However, in the case where the laser beam generator 500 and the beam shifting module 600 are directly connected with each other, a sufficient space in which both the laser beam generator 500 and the beam shifting module 600 are provided has to be ensured, and therefore the degree of freedom in design may be lower than that in the embodiment of FIG. 8.

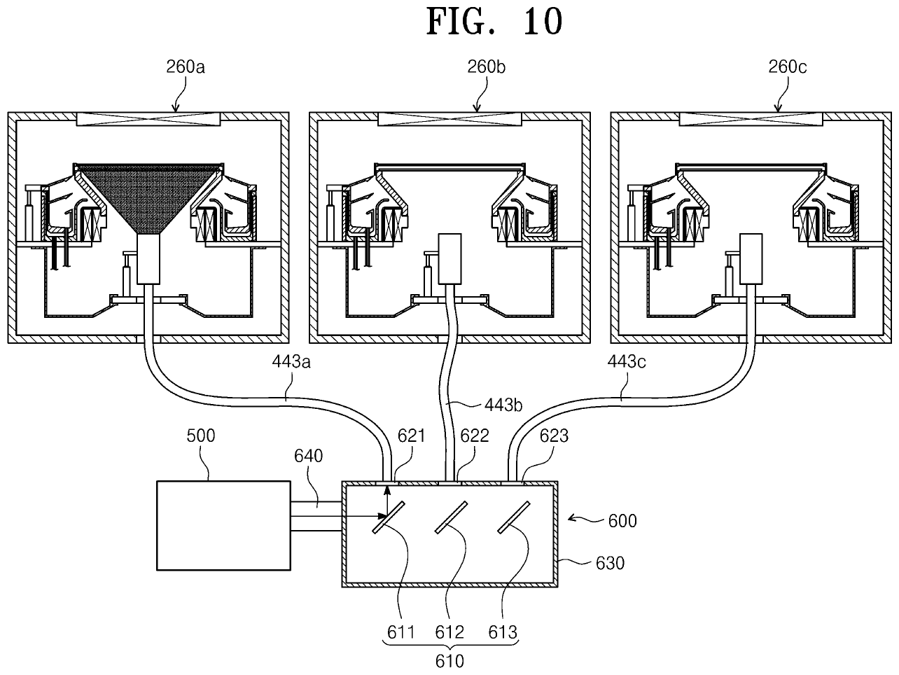

FIGS. 10 to 12 sequentially illustrate operations of substrate treating equipment to which the beam shifting module 600 according to the first embodiment of the inventive concept is applied.

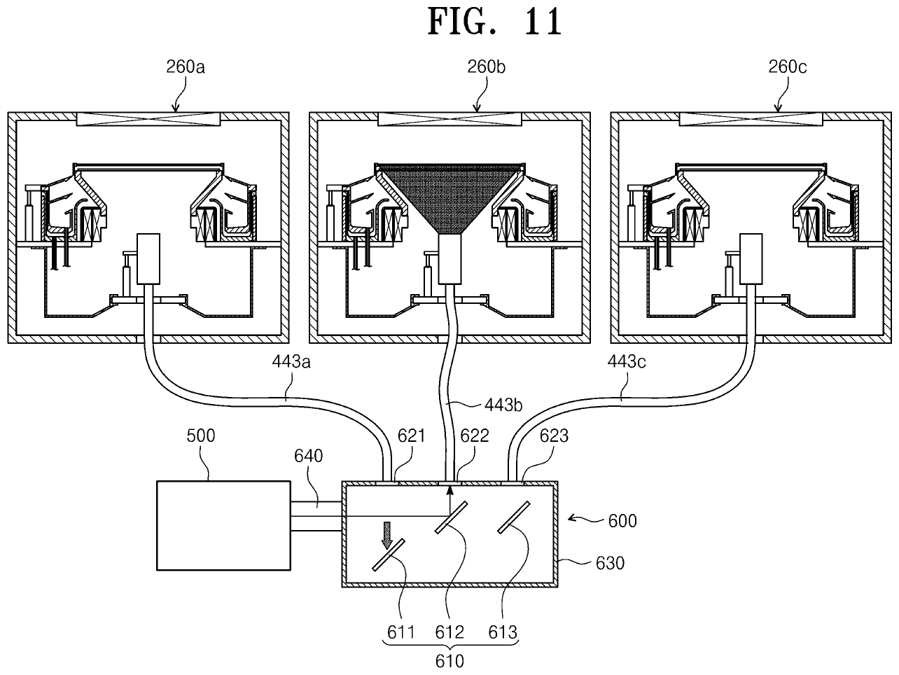

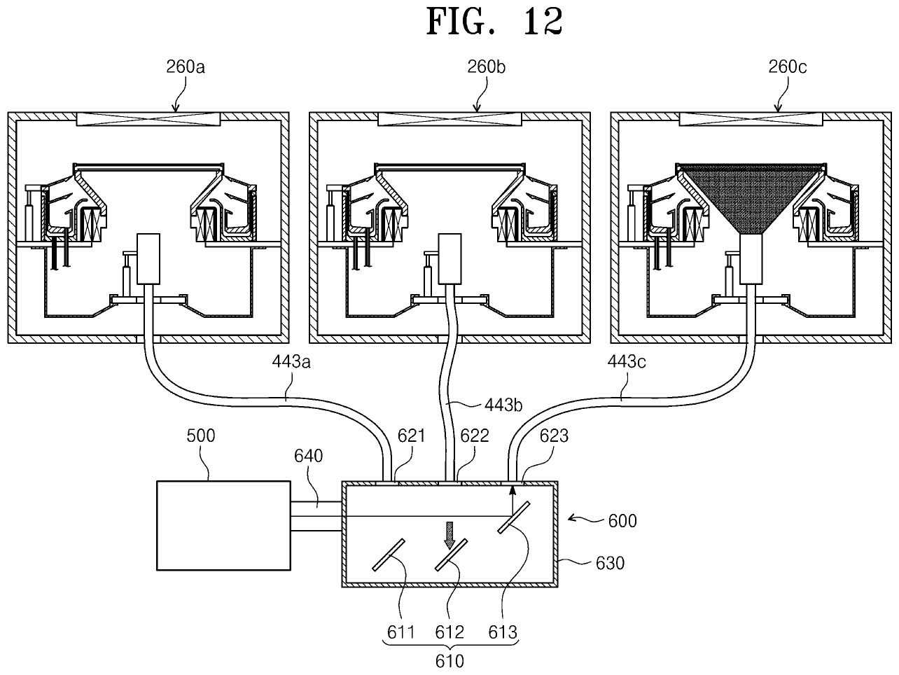

Referring to FIG. 10, the first mirror 611 is located in the first position and reflects a laser beam to deliver the laser beam to the first process chamber 260a corresponding to the first mirror 611. Referring to FIG. 11, the first mirror 611 is moved to the second position and does not change the path of the laser beam. In other words, the first mirror 611 is moved to the second position, and the laser beam moves straight ahead without interference with the first mirror 611. The laser beam is reflected by the second mirror 612 and delivered to the second process chamber 260b corresponding to the second mirror 612. Referring to FIG. 12, the second mirror 612 is moved to the second position and does not change the path of the laser beam. In other words, the second mirror 612 is moved to the second position, and the laser beam moves straight ahead without interference with the first mirror 611 and the second mirror 612. The laser beam is reflected by the third mirror 613 and delivered to the third process chamber 260c corresponding to the third mirror 613. As described above with reference to FIGS. 10 to 12, the laser beam generated and delivered by the laser beam generator 500 may be sequentially delivered to the first process chamber 260a, the second process chamber 260b, and the third process chamber 260c by operation of the mirror unit 610.

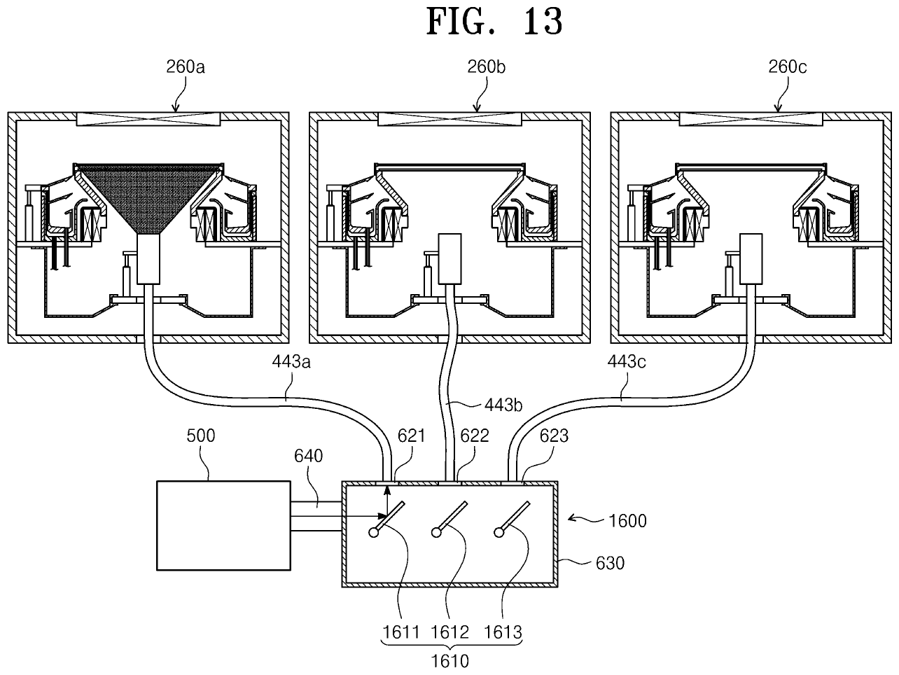

FIGS. 13 to 15 sequentially illustrate operations of substrate treating equipment to which a beam shifting module 1600 according to a second embodiment of the inventive concept is applied.

First, the beam shifting module 1600 according to the second embodiment of the inventive concept and operations of the substrate treating equipment will be described with reference to FIG. 13. The beam shifting module 1600 includes a mirror unit 1610. The mirror unit 1610 includes as many mirrors as a first group of process chambers 260. For example, three process chambers 260a, 260b, and 260c are illustrated as an example of the first group of process chambers 260. Three mirrors 1611, 1612, and 1613 corresponding to the three process chambers 260a, 260b, and 260c, respectively, are illustrated. The first mirror 1611 forms an optical path provided for the first process chamber 260a. The first mirror 1611 delivers a laser beam to a first laser beam delivery member 443a directed toward the first process chamber 260a. The second mirror 1612 forms an optical path provided for the second process chamber 260b. The second mirror 1612 delivers a laser beam to a first laser beam delivery member 443b directed toward the second process chamber 260b. The third mirror 1613 forms an optical path provided for the third process chamber 260c. The third mirror 1613 delivers a laser beam to a first laser beam delivery member 443c directed toward the third process chamber 260c. Each of the mirrors provided in the mirror unit 1610 is independently movable between a first position and a second position. The first position is a position in which the mirror forms a path along which a laser beam is reflected and delivered to a corresponding process chamber, and the second position is a position to which the mirror is rotated about a rotary shaft from the first position and in which the mirror does not change a path of a laser beam. The movement of the mirror may be performed by driving a motor connected to the rotary shaft.

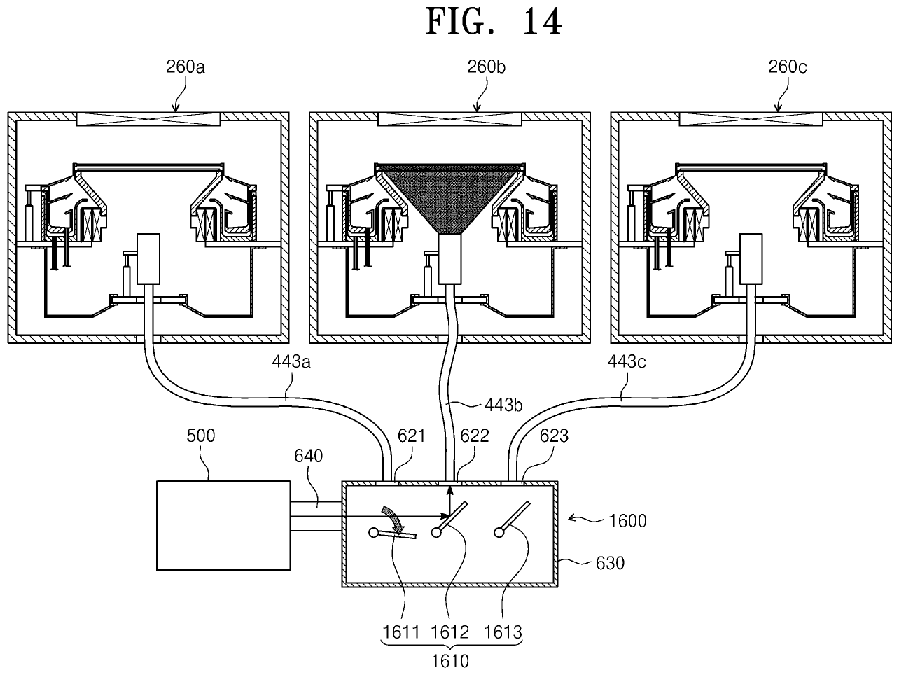

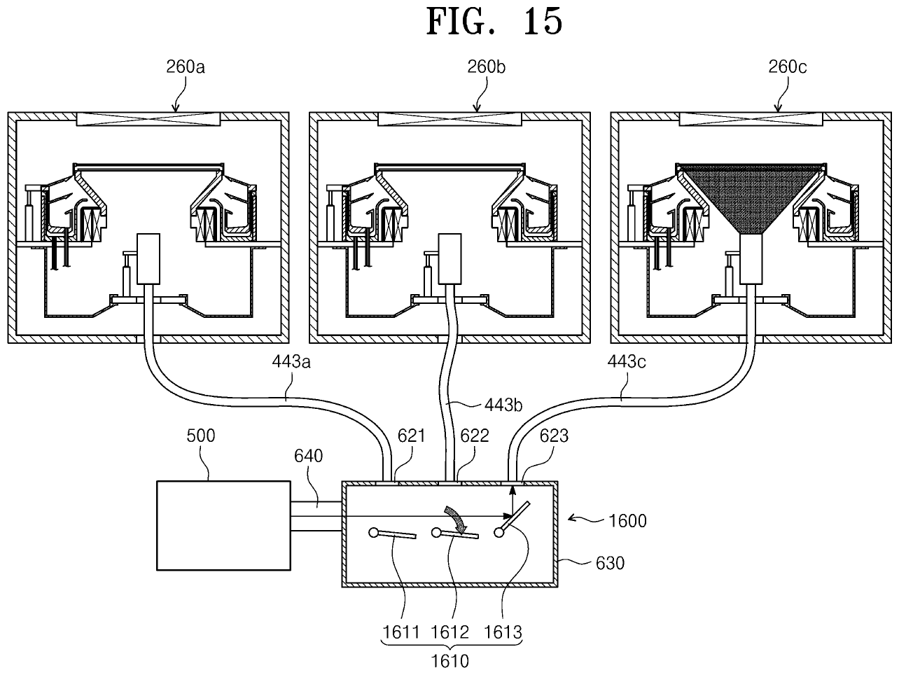

Referring to FIG. 13, the first mirror 1611 is located in the first position and reflects a laser beam to deliver the laser beam to the first process chamber 260a corresponding to the first mirror 1611. Referring to FIG. 14, the first mirror 1611 is moved to the second position and does not change the path of the laser beam. In other words, the first mirror 1611 is moved to the second position, and the laser beam moves straight ahead without interference with the first mirror 1611. The laser beam is reflected by the second mirror 1612 and delivered to the second process chamber 260b corresponding to the second mirror 612. Referring to FIG. 15, the second mirror 1612 is moved to the second position and does not change the path of the laser beam. In other words, the second mirror 1612 is moved to the second position, and the laser beam moves straight ahead without interference with the first mirror 1611 and the second mirror 1612. The laser beam is reflected by the third mirror 1613 and delivered to the third process chamber 260c corresponding to the third mirror 1613. As described above with reference to FIGS. 13 to 15, the laser beam generated and delivered by the laser beam generator 500 may be sequentially delivered to the first process chamber 260a, the second process chamber 260b, and the third process chamber 260c by operation of the mirror unit 1610.

In the above-described embodiment, the three process chambers 260 have been described as an example. However, the number of process chambers 260 may be increased or decreased in consideration of the use and footprint of the equipment. When the number of process chambers 260 is increased or decreased, the number of corresponding mirrors may also be increased or decreased accordingly.

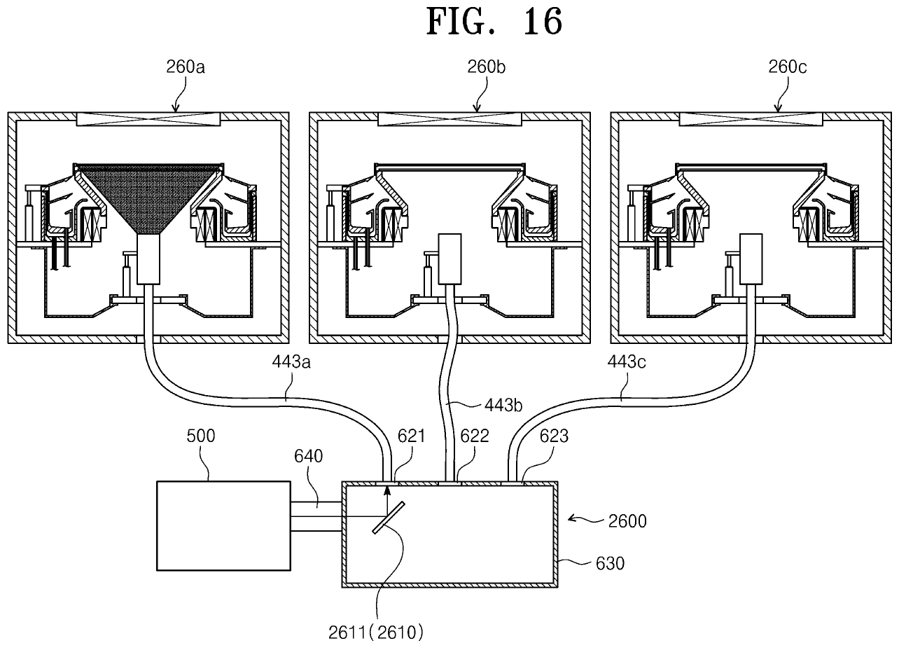

FIGS. 16 to 18 sequentially illustrate operations of substrate treating equipment to which a beam shifting module 2600 according to a third embodiment of the inventive concept is applied.

First, the beam shifting module 2600 according to the third embodiment of the inventive concept and operations of the substrate treating equipment will be described with reference to FIG. 16. The beam shifting module 2600 includes a mirror unit 2610. The mirror unit 2610 is movable to correspond to a first group of process chambers 260. For example, three process chambers 260a, 260b, and 260c are illustrated as an example of the first group of process chambers 260. One first mirror 2611 capable of delivering a laser beam to each of the three process chambers 260a, 260b, and 260c is illustrated. In a first position, the first mirror 2611 forms an optical path provided for the first process chamber 260a. The first mirror 2611 delivers a laser beam to a first laser beam delivery member 443a directed toward the first process chamber 260a. The first mirror 2611 is moved to a second position and forms an optical path provided for the second process chamber 260b. The first mirror 2611 delivers the laser beam to a first laser beam delivery member 443b directed toward the second process chamber 260b. The first mirror 2611 is moved to a third position and forms an optical path provided for the third process chamber 260c. The first mirror 2611 delivers the laser beam to a first laser beam delivery member 443c directed toward the third process chamber 260c. The first mirror 2611 provided in the mirror unit 2610 is movable between the first position, the second position, and the third position. The first position is a position in which the first mirror 2611 forms a path along which a laser beam is reflected and delivered to the first process chamber 260a. The second position is a position to which the first mirror 2611 moves backward from the first position and in which the first mirror 2611 forms a path along which a laser beam is reflected and delivered to the second process chamber 260b. The third position is a position to which the first mirror 2611 moves backward from the second position and in which the first mirror 2611 forms a path along which a laser beam is reflected and delivered to the third process chamber 260c. The movement of the first mirror 2611 may be performed by driving a linear motor (not illustrated) that is connected with the first mirror 2611.

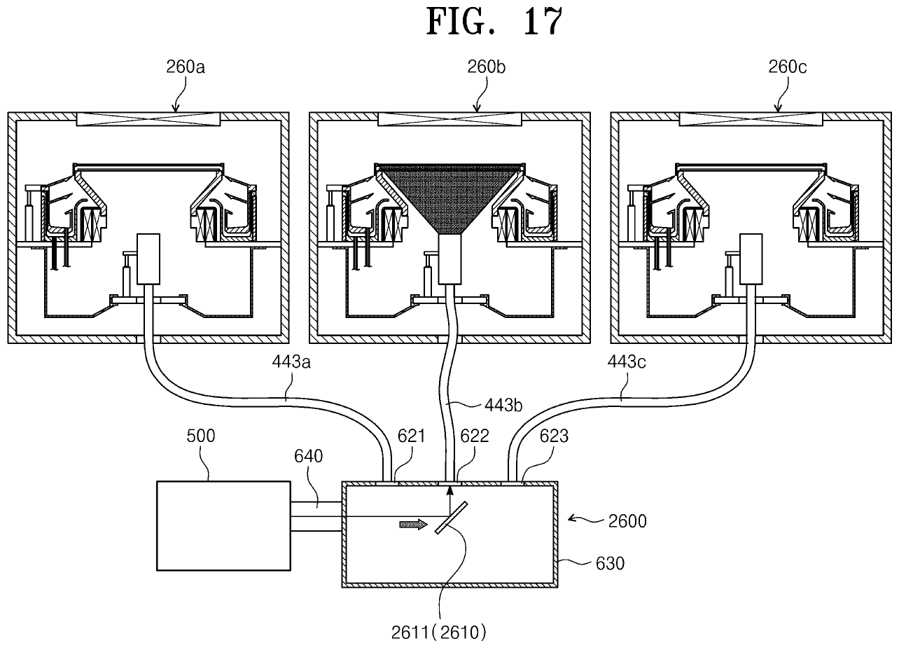

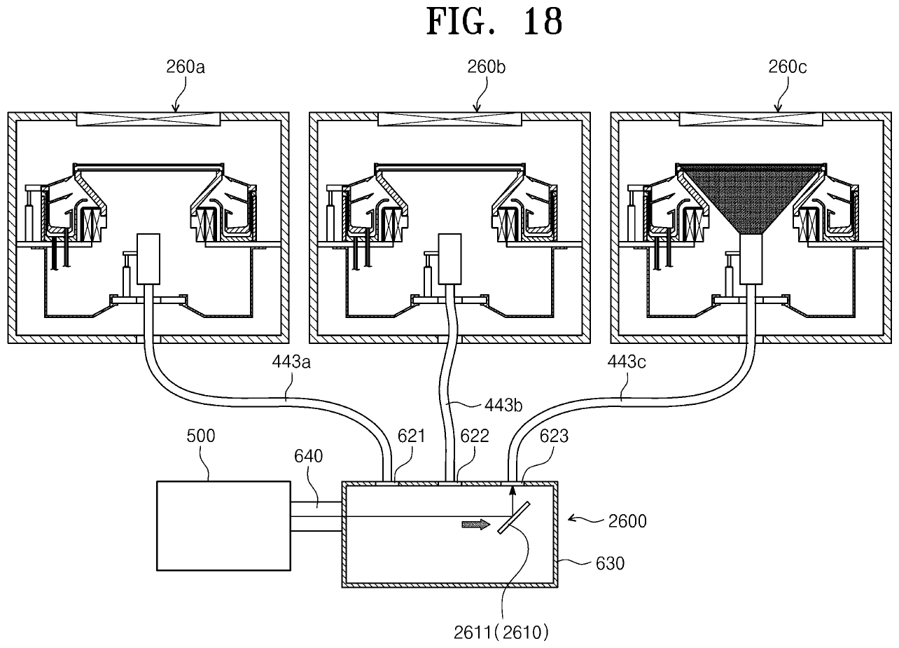

Referring to FIG. 16, the first mirror 2611 is located in the first position and reflects a laser beam to deliver the laser beam to the first process chamber 260a corresponding to the first mirror 2611. Referring to FIG. 17, the first mirror 2611 is moved to the second position, and the laser beam is reflected by the first mirror 2611 located in the second position and is delivered to the second process chamber 260b. Referring to FIG. 18, the first mirror 2611 is moved to the third position, and the laser beam is reflected by the first mirror 2611 located in the third position and is delivered to the third process chamber 260c. As described above with reference to FIGS. 16 to 18, the laser beam generated and delivered by the laser beam generator 500 may be sequentially delivered to the first process chamber 260a, the second process chamber 260b, and the third process chamber 260c by operation of the mirror unit 2610.

In the above-described embodiment, the three process chambers 260 have been described as an example. However, the number of process chambers 260 may be increased or decreased in consideration of the use and footprint of the equipment.

In the first and second embodiment, When the number of process chambers 260 is increased or decreased, the number of corresponding mirrors may also be increased or decreased accordingly.

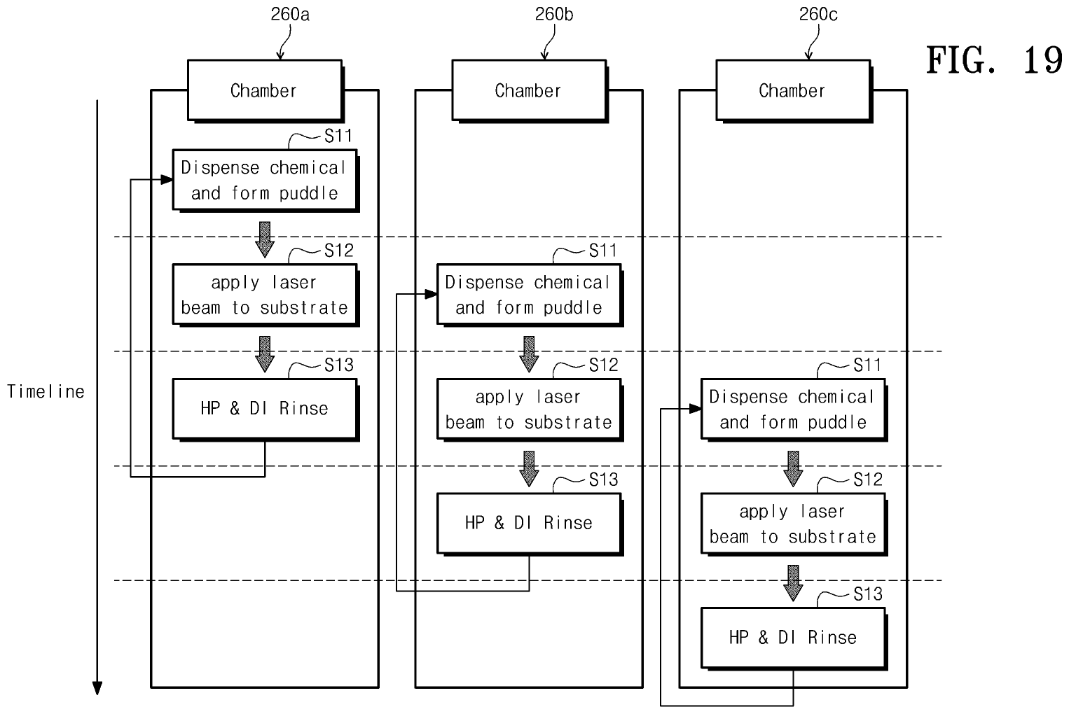

FIG. 19 is a flowchart illustrating a method for operating substrate treating equipment according to an embodiment of the inventive concept. In the flowchart of FIG. 19, the passage of time is represented by a timeline.

According to an embodiment, a pre-process of dispensing a chemical and forming a puddle of the chemical on a substrate W is performed in the first process chamber 260a before laser heating (S11). The chemical may be a liquid that increases process efficiency by being heated. According to an embodiment, the chemical may be a liquid containing phosphoric acid. Although the process of forming the puddle of the chemical is exemplified, a different process may be performed before the laser heating.

After the pre-process, the substrate W is heated by applying a laser beam to the substrate W in the first process chamber 260a (S12). While step S12 is performed in the first process chamber 260a, step S11 that is a pre-process before laser heating is performed in the second process chamber 260b.

When step S12 of heating the substrate W by applying the laser beam to the substrate W in the first process chamber 260a is completed, a post-process of rinsing the chemical is performed (S13). At this time, a rinsing solution may be an aqueous solution of phosphoric acid, SC-1, DI, IPA, or the like. Although the process of rinsing the chemical is exemplified, a different process may be performed after the laser heating. While step S13 is performed in the first process chamber 260a, step S12 of heating a substrate W by applying a laser beam to the substrate W is performed in the second process chamber 260b. Furthermore, while step S12 is performed in the second process chamber 260b, step S11 is performed in the third process chamber 260c.

When the post-process is completely performed on the substrate W in the first process chamber 260a, step S11 that is a pre-process before laser heating may be performed again in the first process chamber 260a. At this time, step S13 that is a post-process after laser heating is performed on the substrate W in the second process chamber 260b. Furthermore, step S12 of heating a substrate W by applying a laser beam to the substrate W is performed in the third process chamber 260c.

When step S12 of heating the substrate W by applying the laser beam to the substrate W in the third process chamber 260c is completed, step S12 of heating the substrate W by applying the laser beam to the substrate W in the first process chamber 260a may be performed again. At this time, step S13 that is a post-process after laser heating is performed on the substrate W in the third process chamber 260c. Furthermore, step S11 may be performed in the second process chamber 260b.

Steps S11, S12, and S13 may be repeated a plurality of times. For example, steps S11, S12, and S13 may be repeated four or more times.

In the case of using the substrate treating equipment and the method for operating the substrate treating equipment according to the embodiments of the inventive concept, the plurality of process chambers 260 may share the one laser beam generator 500, and thus manufacturing cost may be reduced. Further, an effect of decreasing footprint may be achieved through the relatively simple configurations of the beam shifting modules 600, 1600, and 2600. Furthermore, the plurality of process chambers 260 may be efficiently operated without delay using a laser beam generated from the one laser beam generator 500. Moreover, a reduction in process time and an improvement in treatment efficiency may be achieved by sequentially operating the process chambers 260.

In addition, according to the embodiments of the inventive concept, laser beam intensity may be adjusted by adjusting the distance between the end portion of the first laser beam delivery member 443 and the lens unit 442b. Accordingly, heating conditions depending on different environments for the respective process chambers 260 may be changed even though the one laser beam generator 500 is used.

To sequentially deliver a high-power laser beam for treating (e.g., heating) a substrate W to a plurality of process chambers, the embodiments of the inventive concept may be modified into various application examples. The process chambers may be chambers for heating rather than chambers for cleaning or etching. For example, the process chambers may be annealing chambers.

The laser beam generator 500 and the beam shifting module 600, 1600, or 2600 according to the embodiments of the inventive concept may be provided in a lower layer in which the process chambers 260 are provided. For example, in a case where a first group of process chambers 260 are provided in a row and a second group of process chambers 260 are provided in a row under the first group of process chambers 260, a separate space may be provided in a layer between the first group and the second group or in a layer under the second group, and the laser beam generator 500 and the beam shifting module 600, 1600, or 2600 may be provided in the separate space. A laser beam generator 500 and a beam shifting module 600, 1600, or 2600 that apply a laser beam to the first group of process chambers 260 may be provided separately from a laser beam generator 500 and a beam shifting module 600, 1600, or 2600 that apply a laser beam to the second group of process chambers 260.

As described above, according to the embodiments of the inventive concept, etching performance by the substrate treating apparatuses may be improved.

According to the embodiments of the inventive concept, the temperature of a substrate may be rapidly raised and lowered and may thus be accurately controlled.

According to the embodiments of the inventive concept, in heating a substrate by applying a laser beam to the substrate, light distribution may be effectively adjusted.

According to the embodiments of the inventive concept, in heating a substrate by applying a laser beam to the substrate, light intensity may be effectively adjusted.

According to the embodiments of the inventive concept, manufacturing cost of the substrate treating equipment may be reduced.

According to the embodiments of the inventive concept, the footprint of the substrate treating equipment (the amount of space occupied by the equipment) may be decreased.

According to the embodiments of the inventive concept, processes may be performed without delay in a plurality of substrate treating apparatuses using a single laser beam generator.

According to the embodiments of the inventive concept, heating conditions depending on different environments for respective process chambers may be changed despite using a single laser beam generator.

Effects of the inventive concept are not limited to the above-described effects, and any other effects not mentioned herein may be clearly understood from this specification and the accompanying drawings by those skilled in the art to which the inventive concept pertains.

While the inventive concept has been described with reference to embodiments, it will be apparent to those skilled in the art that various changes and modifications may be made without departing from the spirit and scope of the inventive concept. Therefore, it should be understood that the above embodiments are not limiting, but illustrative.

What is claimed is:

1. Substrate treating equipment comprising:
a first process chamber group including a plurality of process chambers, each of which includes a laser beam emitting unit configured to apply a laser beam to a substrate to heat the substrate;
one laser beam generator configured to generate the laser beam applied to the substrate through the laser beam emitting unit of each of the plurality of process chambers included in the first process chamber group; and
a beam shifting module including one or more mirrors corresponsble to the plurality of process chambers included in the first process chamber group,
wherein each of the one or more mirrors is shifted to a position in which the mirror forms an optical path of the laser beam toward a predetermined one of the plurality of process chambers.

2. The substrate treating equipment of claim 1, wherein the beam shifting module includes a plurality of mirrors corresponding to the plurality of process chambers included in the first process chamber group, and
wherein each of the plurality of mirrors is shifted between a first position in which the mirror forms an optical path of the laser beam toward a corresponding one of the plurality of process chambers and a second position in which the mirror does not obstruct the optical path of the laser beam.

3. The substrate treating equipment of claim 2, wherein each of the plurality of mirrors is shifted between the first position and the second position by rectilinear movement.

4. The substrate treating equipment of claim 2, wherein each of the plurality of mirrors is shifted between the first position and the second position by tilting.

5. The substrate treating equipment of claim 4, wherein the tilting is performed with a rotary shaft provided for the mirror as a center.

6. The substrate treating equipment of claim 1, wherein the beam shifting module includes one mirror, and
wherein the one mirror is sequentially shifted to positions in each of which the one mirror forms an optical path of the laser beam toward a corresponding one of the plurality of process chambers.

7. The substrate treating equipment of claim 1, wherein the beam shifting module is optically connected to the laser beam emitting unit of each of the plurality of process chambers by a laser beam delivery member provided to correspond to the laser beam emitting unit.

8. The substrate treating equipment of claim 7, wherein the laser beam delivery member is implemented with an optical fiber.

9. The substrate treating equipment of claim 1, wherein the one laser beam generator has a power output of several kW.

10. The substrate treating equipment of claim 1, wherein each of the plurality of process chambers further includes:
a substrate support unit configured to support and rotate the substrate; and
a liquid dispensing unit including a chemical dispensing nozzle configured to dispense a chemical onto the substrate supported on the substrate support unit.

11. The substrate treating equipment of claim 10, wherein the substrate support unit includes:
a window member disposed under the substrate and formed of a material through which the laser beam emitted from the laser beam emitting unit is able to transmit;
a chuck pin configured to support a lateral portion of the substrate and space the substrate apart from the window member at a predetermined interval;
a spin housing having an empty space extending therethrough in an up/down direction, the spin housing being coupled with the window member and configured to provide a path along which the laser beam is delivered; and
a drive member configured to rotate the spin housing, and
wherein the laser beam emitting unit is disposed under the window member.

12. The substrate treating equipment of claim 10, wherein the chemical dispensed by the liquid dispensing unit is a liquid containing phosphoric acid.

13. The substrate treating equipment of claim 10, further comprising:
a controller,
wherein each of the plurality of process chambers performs:
a first process of dispensing the chemical onto the substrate; and
a second process of heating the substrate with the laser beam, and
wherein the controller:
performs control such that each of the plurality of process chambers included in the first process chamber group sequentially performs the first process and the second process over time and the plurality of process chambers simultaneously perform difference processes; and
controls the beam shifting module such that the one or more mirrors form an optical path toward one process chamber in which the second process is performed, among the plurality of process chambers and deliver the laser beam generated from the one laser beam generator to the one process chamber in which the second process is performed.

14. The substrate treating equipment of claim 10, further comprising:
a controller,
wherein the beam shifting module includes a plurality of mirrors corresponding to the plurality of process chambers included in the first process chamber group, and each of the plurality of mirrors is shifted between a first position in which the mirror forms an optical path of the laser beam toward a corresponding one of the plurality of process chambers and a second position in which the mirror does not obstruct the optical path of the laser beam,
wherein each of the process chambers performs:
a first process of dispensing the chemical onto the substrate; and
a second process of heating the substrate with the laser beam, and
wherein the controller:
performs control such that each of the plurality of process chambers included in the first process chamber group sequentially performs the first process and the second process over time and the plurality of process chambers simultaneously perform difference processes; and
controls the beam shifting module such that a mirror configured to form an optical path toward one process chamber in which the second process is performed among the plurality of process chambers is located in the first position, a mirror located on an upstream side of the optical path formed by the mirror located in the first position among the plurality of mirrors is located in the second position, and the laser beam generated from the one laser beam generator is delivered to the one process chamber in which the second process is performed.

15. The substrate treating equipment of claim 13, wherein each of the plurality of process chambers additionally performs a third process of dispensing a rinsing solution onto the substrate and replacing the chemical with the rinsing solution, and
wherein each of the plurality of process chambers included in the first process chamber group sequentially performs the first process, the second process, and the third process over time.

16. The substrate treating equipment of claim 7, wherein the laser beam emitting unit includes a lens module including at least one lens unit, the lens module being configured to refract the laser beam to process the laser beam into a shape corresponding to the substrate, and
wherein a distance between the lens unit of the lens module and an end portion of the laser beam delivery member is adjustable.

17. The substrate treating equipment of claim 1, wherein each of the plurality of process chambers further includes a stage configured to move the laser beam emitting unit upward and downward to adjust a distance between the laser beam emitting unit and the substrate.

18. Substrate treating equipment comprising:
a first process chamber group including a plurality of process chambers;
one laser beam generator configured to generate a laser beam;
a beam shifting module including a plurality of mirrors corresponding to the plurality of process chambers included in the first process chamber group; and
a controller,
wherein each of the plurality of process chambers includes:
a substrate support unit configured to support and rotate a substrate;
a liquid dispensing unit including a chemical dispensing nozzle configured to dispense a chemical onto the substrate supported on the substrate support unit; and
a laser beam emitting unit configured to apply the laser beam to the substrate to heat the substrate,
wherein the substrate support unit includes:
a window member disposed under the substrate and formed of a material through which the laser beam emitted from the laser beam emitting unit is able to transmit;
a chuck pin configured to support a lateral portion of the substrate and space the substrate apart from the window member at a predetermined interval;
a spin housing having an empty space extending therethrough in an up/down direction, the spin housing being coupled with the window member and configured to provide a path along which the laser beam is delivered; and
a drive member configured to rotate the spin housing,
wherein the laser beam emitting unit is disposed under the window member,
wherein the beam shifting module is optically connected by a laser beam delivery member connected with the laser beam emitting unit of each of the plurality of process chambers,
wherein each of the plurality of mirrors is shifted between a first position in which the mirror forms an optical path of the laser beam toward a corresponding one of the plurality of process chambers and a second position in which the mirror does not obstruct the optical path of the laser beam, and
wherein the controller performs control such that a mirror configured to form an optical path toward a selected one of the plurality of process chambers is located in the first position, a mirror located on an upstream side of the optical path formed by the mirror located in the first position among the plurality of mirrors is located in the second position, and the laser beam generated from the one laser beam generator is delivered to the selected process chamber.
